(19) United States
(12) Patent Application Publication
(10) Pub. No.: US 2025/0167737 A1
(43) Pub. Date: May 22, 2025

(54) AMPLIFICATION CONTROL CIRCUIT AND AMPLIFICATION CONTROL METHOD

(71) Applicant: RichWave Technology Corp., Taipei City (TW)

(72) Inventor: Yi-Fong Wang, Taipei City (TW)

(73) Assignee: RichWave Technology Corp., Taipei City (TW)

(21) Appl. No.: 18/393,583

(22) Filed: Dec. 21, 2023

(30) Foreign Application Priority Data
Nov. 17, 2023 (TW) 112144467

(51) Int. Cl. H03F 1/30; H03F 1/02

(52) U.S. Cl. CPC H03F 1/30; H03F 1/0211

(57) ABSTRACT

An amplifier control circuit includes a first bias unit and a second bias unit. The first bias unit outputs a first current to a first amplifier. The first bias unit includes a primary bias circuit and a preheat signal generation circuit. The primary bias circuit receives an operational voltage signal, outputs the first current and outputs a detection signal. Change of the operational voltage signal is related to change of the detection signal. The preheat signal generation circuit generates a preheat control signal according to the change of the detection signal. The second bias circuit outputs a second current to a second amplifier. The second current in a first period is larger than the second current in a second period. The first period starts after the operational voltage signal starts to change, and the second period starts after the first period ends.

### TECHNICAL FIELD

The disclosure is related to an amplification control circuit and an amplification control method, and more particularly, an amplification control circuit and an amplification control method capable of detecting an input-stage amplifier to preheat an output-stage amplifier accordingly.

### BACKGROUND

Amplifiers are widely used in current electronic devices for signal processing and amplification. However, when an amplifier starts operating, since the temperature of the amplifier has not yet reached thermal equilibrium, the waveform of the modulated signal outputted by the amplifier will be distorted. The distortion will increase the time required by the amplifier to enter a stable state from an unstable state, so it takes more time for the amplifier to output a stable signal, and the distortion is detrimental to the operation of the amplifier. Currently, a solution is still in need to speed up the temperature equilibrium of the amplifier to avoid excessive circuit area and complexity.

### SUMMARY

An embodiment provides an amplification control circuit. The amplification control circuit comprises a first bias unit and a second bias unit. The first bias unit is configured to receive an operational voltage signal, output a first current to a first amplifier, and generate a preheat control signal according to a change of the operational voltage signal. The second bias unit is configured to output a second current to a second amplifier, and comprises a first terminal configured to receive the preheat control signal, and a second terminal configured to output the second current. The second current in a first period is larger than the second current in a second period, the first period starts from a beginning of the change of the operational voltage signal, and the second period starts from an end of the first period.

An amplification control method comprises receiving an operational voltage signal and outputting a first current to a first amplifier, generating a preheat control signal according to a change of the operational voltage signal, and outputting a second current to a second amplifier according to the preheat control signal. The second current in a first period is larger than the second current in a second period, the first period starts from a beginning of the change of the operational voltage signal, and the second period starts from an end of the first period.

### BRIEF DESCRIPTION OF THE DRAWINGS

FIG. 1 illustrates an amplification control circuit coupled to a plurality of amplifiers according to an embodiment.

FIG. 2 illustrates waveforms of signals in the embodiment of FIG. 1

FIG. 3 illustrates the first bias unit of FIG. 1 according to an embodiment.

FIG. 4 illustrates the main bias circuit of FIG. 1 according to an embodiment.

FIG. 5 illustrates the preheat signal generation circuit of FIG. 1 according to an embodiment.

FIG. 6 illustrates the preheat control generation circuit of FIG. 1 according to an embodiment.

FIG. 7 illustrates the second bias unit of FIG. 1 according to an embodiment.

FIG. 8 illustrates the amplification control circuit coupled to the amplifiers according to another embodiment.

FIG. 9 illustrates the amplification control circuit coupled to the amplifiers according to another embodiment.

FIG. 10 illustrates the amplification control circuit coupled to the amplifiers according to another embodiment.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

In the text, voltages of signals are examples. According to requirements, the voltages of the signals can be adjusted. In the text, when it mentions a component can be disposed or used optionally, it means the component can be used or not used according to requirements.

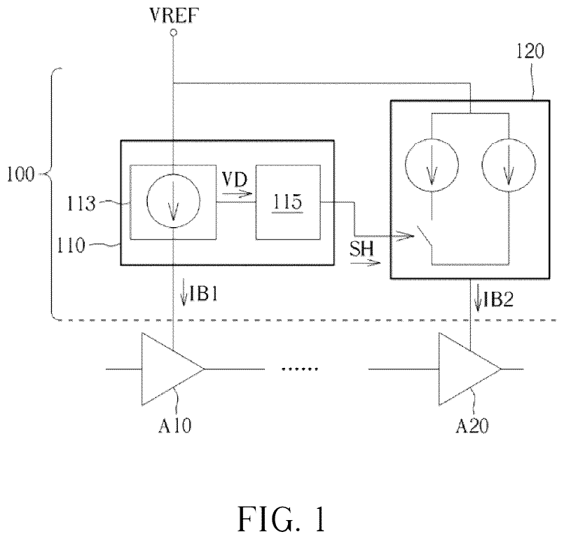

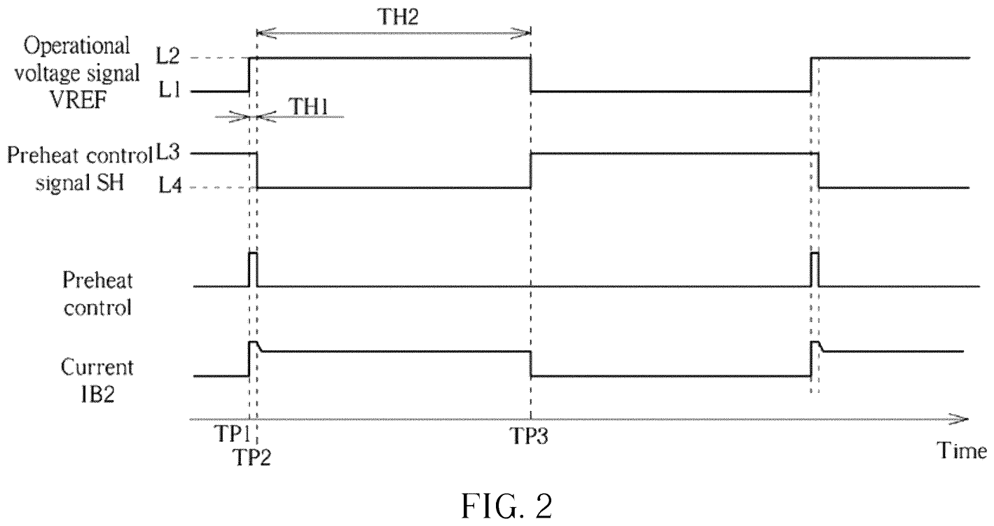

FIG. 1 illustrates an amplification control circuit 100 coupled to a plurality of amplifiers according to an embodiment. FIG. 2 illustrates waveforms of signals in FIG. 1. The amplification control circuit 100 can include a first bias unit 110 and a second bias unit 120. The first bias unit 110 can receive an operational voltage signal VREF, output a current IB1 to a first amplifier A10, and generate a preheat control signal SH according to a change of the operational voltage signal VREF. The second bias unit 120 can output a current IB2 to a second amplifier A20. The second bias unit 120 can include a first terminal and a second terminal, where the first terminal can be coupled to a second terminal of a preheat signal generation circuit 115 of the first bias unit 110 to receive the preheat control signal SH, and the second terminal can output the current IB2 to the amplifier A20. In this embodiment, the amplifiers A10 and A20 can be an input-stage amplifier and an output-stage amplifier respectively. The currents IB1 and IB2 can be bias currents for the amplifiers A10 and A20 respectively to operate the amplifiers A10 and A20 appropriately.

The first bias unit 110 can include a main bias circuit 113 and the preheat signal generation circuit 115. The main bias circuit 113 can include a first terminal, a second terminal and a detection terminal, where the first terminal can receive the operational voltage signal VREF, the second terminal can output the current IB1, and the detection terminal can output a detection signal VD. The change of the operational voltage signal VREF can be related to a change of the detection signal VD. For example, the operational voltage signal VREF can be controlled to be 0 volts or 3 volts. When the operational voltage signal VREF is 0 volts, the amplifiers A10 and A20 can be turned off. When the operational voltage signal VREF is 3 volts, the amplifiers A10 and A20 can be turned on. For example, when the operational voltage signal VREF is 0 volts, the detection voltage can be 0 volts, and when the operational voltage signal VREF is 3 volts, the detection voltage can be 1.3 volts.

The preheat signal generation circuit 115 can generate the preheat control signal SH according to the change of the detection signal VD. The preheat signal generation circuit 115 can include a first terminal and the second terminal, where the first terminal can be coupled to the detection terminal of the main bias circuit 113 to receive the detection signal VD, and the second terminal can output the preheat control signal SH.

As shown in FIG. 1 and FIG. 2, The current IB2 in a first period TH1 can be larger than the current IB2 in a second period TH2. Hence, the current IB2 can be used to preheat the amplifier A20 in the first period TH1. As a result, the amplifier A20 can reach thermal equilibrium earlier, reducing signal distortion.

The first period TH1 can start from a beginning of the change of the operational voltage signal VREF. The second period TH2 can start from an end of the first period TH1.

The amplifier A10 can be an input-stage amplifier, and the amplifier A20 can be an output-stage amplifier. The current IB2 inputted to the amplifier A20 can be larger than the current IB1 inputted to the amplifier A10. In another embodiment, optionally, an intermediate-stage amplifier can be disposed between the amplifiers A10 and A20. In other embodiments, optionally, another input-stage amplifier can be disposed and coupled to the input terminal of the amplifier A10 to be a previous stage, and/or another output-stage amplifier can be disposed and coupled to the output terminal of the amplifier A20 to be a next stage.

According to an embodiment, the preheat signal generation circuit 115 can further generate the preheat control signal SH according to the change of the detection signal VD and the change of the operational voltage signal VREF concurrently. As shown in FIG. 1 and FIG. 2, when the operational voltage signal VREF is changed from a first signal level L1 to a second signal level L2 (e.g. from 0 volts to 3 volts) at a first time point TP1, the detection signal VD can be changed accordingly (e.g. from 0 volts to 1.3 volts), and the preheat control signal SH can be changed from a third signal level L to a fourth signal level (e.g. from 0.5 volts to 0 volts) at a second time point TP2. The first time point TP1 can precede the second time point TP2. The first period TH1 can be from the time point TP1 to the time point TP2. The current IB2 in the first period TH1 can be larger than the current IB2 in the second period TH2, so the current IB2 can preheat the amplifier A20 in the first period TH1. In FIG. 2, the signal waveform of preheat control can be generated according to a result of the operational voltage signal VREF and the preheat control signal SH affecting one another (e.g. a product or an intersection of, a high/low voltage state of the operational voltage signal VREF and a high/low voltage state of the preheat control signal SH). In the first period TH1 (i.e. the period where the preheat control is enabled), the signal waveform of preheat control can have a pulse, it means the amplifier A20 can be preheated in the first period TH1. As shown in FIG. 2, the second period TH2 can be from the second time point TP2 to a time point TP3, and the operational voltage signal VREF can be changed to the signal level L1 (e.g. 0 volts) at the time point TP3. In periods other than the first period TH1 (e.g. the second period TH2, and other periods where the operational voltage signal VREF is kept at the first signal level L1), the preheat control can be disabled, and the signal waveform of preheat control can be kept at a low signal level. Through the operations mentioned above, the preheat control can be performed in the first period TH1, and the current IB2 in the second period TH2 can be kept unchanged substantially. When the operational voltage signal VREF is kept at the first signal level L1, the second period TH2 can be kept unchanged (e.g. at about 0 volts). Hence, the amplifier A20 is not preheated in the period other than the first period TH1.

As shown in FIG. 1 and FIG. 2, when the operational voltage signal VREF received by the first bias unit 110 is changed to activate the amplifiers A10 and A20, the change of the operational voltage signal VREF can be detected, and the preheat control signal SH can be used to turn on a switch to increase the current IB2 to preheat the output-stage amplifier (e.g. the amplifier A20). Hence, the second bias unit 120 is prevented from preheating the related circuits repeatedly. As a result, the amplifier can be preheated, and the area and complexity of the circuit are reduced.

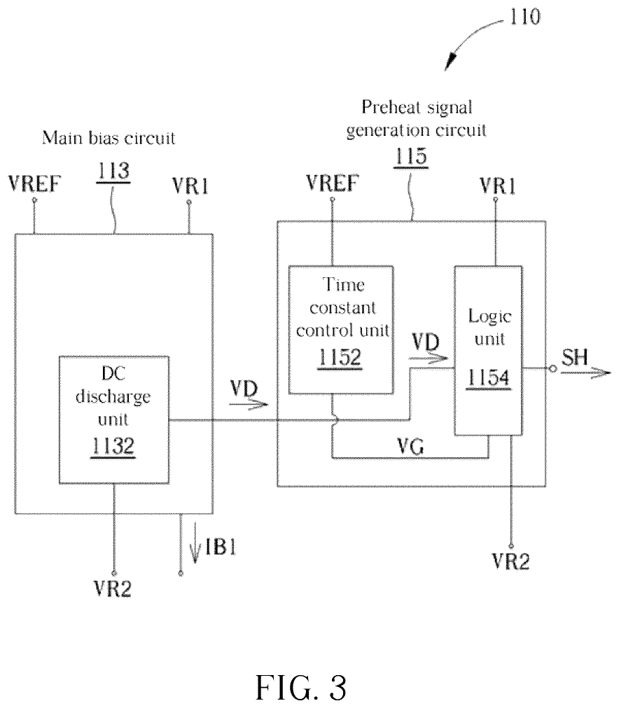

FIG. 3 illustrates the first bias unit 110 of FIG. 1 according to an embodiment. The main bias circuit 113 of the first bias unit 110 can further include a third terminal, a fourth terminal and a direct-current (DC) discharge unit 1132, where the third terminal can receive a first reference voltage VR1 (e.g. 5 volts), and the fourth terminal can receive a second reference voltage VR2 (e.g. 0 volts or a ground voltage). The DC discharge unit 1132 can include a first terminal and a second terminal, where the first terminal can be coupled to the detection terminal of the main bias circuit 113 to output the detection signal VD, and the second terminal can be coupled to the fourth terminal of the main bias circuit 113 to receive the second reference voltage VR2.

The preheat signal generation circuit 115 of the first bias unit 110 can further include a third terminal, a fourth terminal, a fifth terminal, a time constant control unit 1152 and a logic unit 1154, where the third terminal can receive the operational voltage signal VREF, the fourth terminal can receive the first reference voltage VR1, and the fifth terminal can receive the second reference voltage VR2.

The time constant control unit 1152 can include a first terminal and a second terminal, where the first terminal can be coupled to the third terminal of the preheat signal generation circuit 115 to receive the operational voltage signal VREF. The logic unit 1154 can include a first input terminal, a second input terminal and an output terminal, where the first input terminal can be coupled to the first terminal of the preheat signal generation circuit 115 to receive the detection signal VD, the second input terminal can be coupled to the second terminal of the time constant control unit 1152 to receive a signal VG, and the output terminal can be coupled to the second terminal of the preheat signal generation circuit 115 to output the preheat control signal SH.

When the operational voltage signal VREF is changed from the first signal level L1 to the second signal level L2, the time constant control unit 1152 and the logic unit 1154 can be used jointly to generate the preheat control signal SH according to the change of the operational voltage signal VREF. Specifically, the time constant control unit 1152 can generate the signal VG according to the equivalent resistance and capacitance of the time constant control unit 1152 and the operational voltage signal VREF, and the signal VG can change with time. The logic unit 1154 can perform logical processing according to the change of the detection signal VD and the change of the signal VG to generate the preheat control signal SH. The preheat control signal SH can change according the change of the detection signal VD and the change of the signal VG.

When the operational voltage signal VREF is changed from the second signal level L2 to the first signal level L1, the logic unit 1154 can provide a discharge path between the second input terminal (i.e. the terminal for inputting the signal VG) and the first input terminal (i.e. the terminal for inputting the detection signal VD) of the logic unit 1154. Hence, the electric charges of the time constant control unit 1152 can be released through the discharge path and the DC discharge unit 1132 to the fourth terminal (i.e. the terminal receiving the second reference voltage VR2) of the main bias circuit 113, ensuring the preheat signal generation circuit 115 can operate normally when the operational voltage signal VREF is changed from the first signal level L1 to the second signal level L2 again.

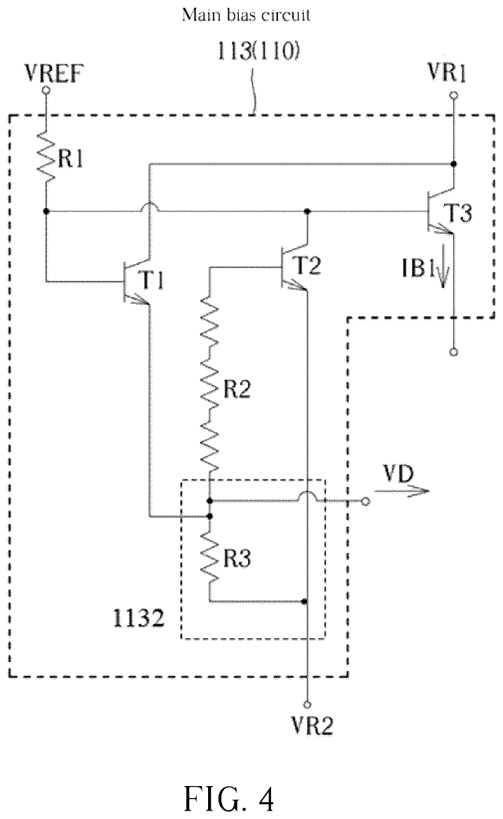

FIG. 4 illustrates the main bias circuit 113 of FIG. 1 according to an embodiment. FIG. 4 is an example, embodiments are not limited thereto, and other appropriate modifications belong to the scope of embodiments. The main bias circuit 113 can include a transistor T1, a transistor T2, a resistor R2, a transistor T3 and a resistor R3.

The transistor T1 can include a first terminal, a second terminal and a control terminal, where the first terminal can be coupled to the third terminal of the main bias circuit 113 to receive the first reference voltage VR1, the second terminal can be coupled to the detection terminal of the main bias circuit 113 (i.e. the terminal outputting the detection signal VD), and the control terminal can be coupled to the first terminal of the main bias circuit 113 to receive the operational voltage signal VREF. Optionally, the control terminal of the transistor T1 and the first terminal of the main bias circuit 113 can be coupled to a resistor R1. The resistor R1 can be disposed in the main bias circuit 113, or be replaced with an external resistor outside the main bias circuit 113.

The transistor T2 can include a first terminal, a second terminal and a control terminal, where the first terminal can be coupled to the control terminal of the transistor T1. The resistor R2 can include a first terminal and a second terminal, where the first terminal can be coupled to the control terminal of the transistor T2, and the second terminal can be coupled to the detection terminal of the main bias circuit 113. The transistor T3 can include a first terminal, a second terminal and a control terminal, where the first terminal can be coupled to the third terminal of the main bias circuit 113 to receive the first reference voltage VR1, the second terminal can be coupled to the second terminal of the main bias circuit 113 to output the current IB1, and the control terminal can be coupled to the first terminal of the transistor T2. The resistor R3 can include a first terminal and a second terminal, where the first terminal can be coupled to the detection terminal of the main bias circuit 113, and the second terminal can be coupled to the fourth terminal of the main bias circuit 113 to receive the second reference voltage VR2.

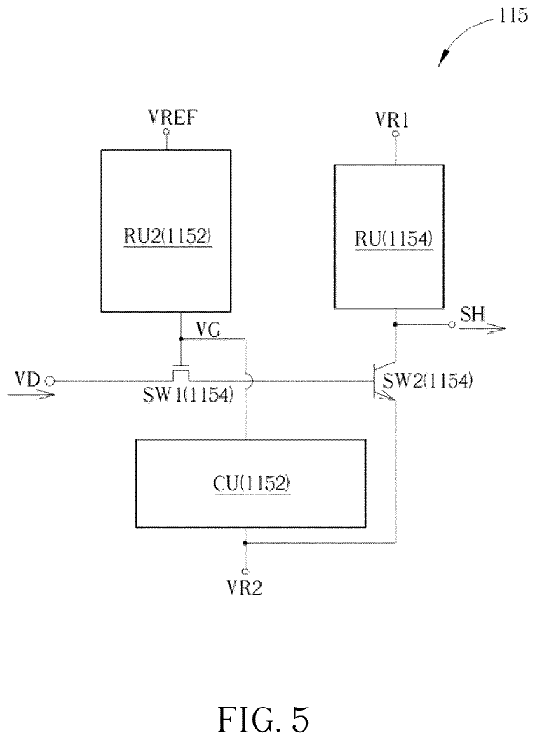

FIG. 5 illustrates the preheat signal generation circuit 115 of FIG. 1 according to an embodiment. FIG. 5 is an example, embodiments are not limited thereto, and other appropriate modifications belong to the scope of embodiments. The preheat signal generation circuit 115 can include the time constant control unit 1152 and the logic unit 1154. The logic unit 1154 can further include a transistor SW1. The transistor SW1 can include a first terminal, a second terminal and a control terminal, where the first terminal can be coupled to the first input terminal of the logic unit 1154 to receive the detection signal VD, and the control terminal can be coupled to the second input terminal of the logic unit 1154 to output the signal VG.

When the operational voltage signal VREF is changed from the second signal level L2 to the first signal level L1, the logic unit 1154 can provide the discharge path between the first input terminal and the second terminal of the logic unit 1154, ensuring the preheat signal generation circuit 115 to operate normally when the operational voltage signal VREF is changed from the first signal level L1 to the second signal level L2 again. When the operational voltage signal VREF is changed from the first signal level L1 to the second signal level L2, the logic unit 1154 can provide a signal transmission path between the first input terminal of the logic unit 1154 and the second terminal of the transistor SW1, and the logic unit 1154 can perform logical processing according to the faster change of the detection signal VD and the slower change of the signal VG to generate the preheat control signal SH. The preheat control signal SH can change correspondingly according the change of the detection signal VD and the change of the signal VG. The slower change of the signal VG may occur because of charging and discharging of an RC (resistor-capacitor) circuit. As for the corresponding change of the preheat control signal SH, when the operational voltage signal VREF is changed from the first signal level L1 to the second signal level L2, after a period (e.g. the first period TH1) elapses, the preheat control signal SH can be changed (e.g. from the third signal level L3 to the fourth signal level L4).

As shown in FIG. 5, the logic unit 1154 can further include a transistor SW2. The transistor SW2 can include a first terminal, a second terminal and a control terminal, where the first terminal can be coupled to the second terminal of the preheat signal generation circuit 115 to output the preheat control signal SH, and the control terminal can be coupled to the second terminal of the transistor SW1.

As shown in FIG. 5, the logic unit 1154 can further include a resistance unit RU. The resistance unit RU can include a first terminal and a second terminal, where the first terminal can receive the first reference voltage VR1, and the second terminal can be coupled to the first terminal of the transistor SW2.

As shown in FIG. 5, the time constant control unit 1152 of the preheat signal generation circuit 115 can include a resistance unit RU2 and a capacitance unit CU. The resistance unit RU2 can include a first terminal and a second terminal, where the first terminal can be coupled to the first terminal of the time constant control unit 1152 to receive the operational voltage signal VREF, and the second terminal can be coupled to the second input terminal of the logic unit 1154 to output the signal VG. The capacitance unit CU can include a first terminal and a second terminal, where the first terminal can be coupled to the second terminal of the resistance unit RU2 to receive the signal VG, and the second terminal can receive the second reference voltage VR2.

The resistance of the resistance unit RU2 and the capacitance of the capacitance unit CU can be adjusted to adjust the periods of charging and discharging, and adjust the waveforms and the length of the first period TH1 in FIG. 2, where the first period TH1 is the period of performing preheating.

When the capacitance unit CU is fully charged through the resistance unit RU2, the signal VG can have a high signal level (e.g. 1.8 volts). When the capacitance CU is fully discharged through the resistance unit RU2, the signal VG can have a low signal level (e.g. 0.5 volts). Through the changes of the signal VG, the transistor SW1 can be turned on or turned off, so the transistor SW2 can be turned on or turned off accordingly, controlling the voltage level of the preheat control signal SH.

For example, when the operational voltage signal VREF is substantially kept unchanged in a period of time, for example, is substantially kept at a low signal level (e.g. 0 volts), the preheat control signal SH can have a high signal level (e.g. 0.5 volts). When the operational voltage signal VREF is being converted to a high signal level (e.g. from 0 volts to 3 volts), the preheat control signal SH can have the high signal level (e.g. 0.5 volts) to perform preheating. When the operational voltage signal VREF is substantially kept unchanged in another period of time, for example, is substantially kept at the high signal level (e.g. 3 volts), the preheat control signal SH can have a low signal level (e.g. 0 volts).

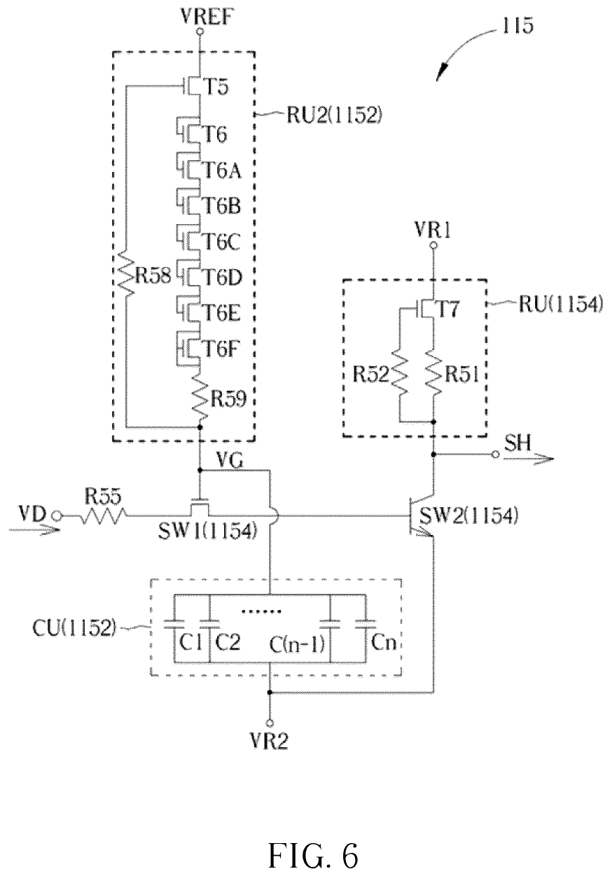

FIG. 6 illustrates the preheat signal generation circuit 115 of FIG. 1 according to an embodiment. In FIG. 6, a resistor R55 coupled between the first terminal of the transistor SW1 and the first input terminal of the logic unit 1154 can be disposed optionally.

The resistance unit RU can further include a transistor T7. The transistor T7 can include a first terminal, a second terminal and a control terminal, where the first terminal can be coupled to the first terminal of the resistance unit RU to receive the first reference voltage VR1, the second terminal can be coupled to the second terminal of the resistance unit RU, and the control terminal can be coupled to the second terminal of the resistance unit RU. The transistor T7 can be a depletion transistor. The transistor T7 can be operated to be close to a pinch-off state, and the transistor T7 can have a high resistance and form a thin film resistor at this time.

The resistance unit RU can further include a resistor R51 and a resistor R52 each including a first terminal and a second terminal. The first terminal of the resistor R51 can be coupled to the second terminal of the transistor T7, and the second terminal of the resistor R51 can be coupled to the second terminal of the resistance unit RU. The first terminal of the resistor R52 can be coupled to the control terminal of the transistor T7, and the second terminal of the resistor R52 can be coupled to the second terminal of the resistance unit RU. The resistor R51 and the resistor R52 can be disposed optionally, so the second terminal of the transistor T7 can be coupled to the second terminal of the resistance unit RU through the resistor R51, and the control terminal of the transistor T7 can be coupled to the second terminal of the resistance unit RU through the resistor R52.

The resistance unit RU2 can further include a transistor T5, a resistor R58 and a transistor T6. The transistor T5 can include a first terminal, a second terminal and a control terminal, where the first terminal can be coupled to the first terminal of the resistance unit RU2 to receive the operational voltage signal VREF. The resistor R58 can include a first terminal and a second terminal, where the first terminal can be coupled to the control terminal of the transistor T5, and the second terminal can be coupled to the second terminal of the resistance unit RU2 to have the signal VG. The transistor T6 can include a first terminal, a second terminal and a control terminal, where the first terminal can be coupled to the second terminal of the transistor T5, the second terminal coupled to the second terminal of the resistance unit RU2, and the control terminal coupled to the first terminal of the transistor T6. The transistor T5 can be a depletion transistor. The transistor T7 can be operated to be close to a pinch-off state to have a high resistance.

As shown in FIG. 6, optionally, the resistance unit RU2 can further include transistors T6A, T6B, T6C, T6D, T6E and T6F. The circuit in FIG. 6 with the transistors T6A to T6F is an example. According to requirements, more or less transistors can be disposed. In the example of FIG. 6, optionally, a first terminal and a control terminal of one of the transistors T6A to T6F can be coupled to one another, and a first terminal and a second terminal of one of the transistors T6A to T6F can be coupled to one another, adjusting the length of the first period TH1 in FIG. 2. Hence, the period of preheating the amplifier A20 is adjustable.

The resistor R58 can protect the transistors in the resistance unit RU2. As shown in FIG. 6, optionally, the resistance unit RU2 can further include a resistor R59 to adjust the resistance of the resistance unit RU2. The resistor R59 can include a first terminal and a second terminal, where the first terminal can be coupled to the second terminal of the transistor T6, and the second terminal can be coupled to the second terminal of the resistance unit RU2. When the operational voltage signal VREF is changed from the second signal level L2 to the first signal level L1, the resistor R58 can provide a discharge path between the second terminal and the first terminal of the resistance unit RU2. The electric charges of the capacitance unit CU can be released to the first terminal of the resistance unit RU2 through the discharge path, ensuring the preheat signal generation circuit 115 can operate normally when the operational voltage signal VREF is changed from the first signal level L1 to the second signal level L2 again.

The capacitance unit CU can further include a plurality of capacitors Cl to Cn, where n is an integer larger than zero. The capacitors Cl to Cn each can include a first terminal and a second terminal, where the first terminal can be coupled to the first terminal of the capacitance unit CU, and the second terminal can be coupled to the second terminal of the capacitance unit CU. In other words, the capacitors Cl to Cn can be coupled in parallel to one another. The number of the capacitors Cl to Cn and the capacitance of each capacitor can be adjusted according to requirements to adjust the length of the first period TH1 in FIG. 2, i.e. the period of preheating the amplifier A20.

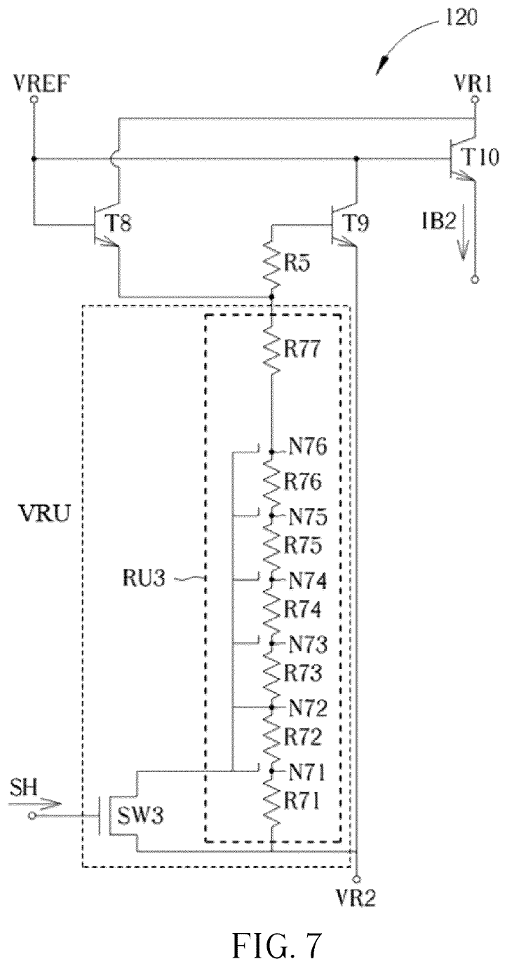

FIG. 7 illustrates the second bias unit 120 of FIG. 1 according to an embodiment. The second bias unit 120 can further include a third terminal, a fourth terminal, a fifth terminal, a transistor T8, a transistor T9, a transistor T10, a resistor R5, a transistor SW3 and a resistance unit RU3, where the third terminal can receive the operational voltage signal VREF, the fourth terminal can receive a first reference voltage VR1, and the fifth terminal can receive a second reference voltage VR2.

The transistor T8 can include a first terminal, a second terminal and a control terminal, where the first terminal can be coupled to the fourth terminal of the second bias unit 120 to receive the first reference voltage VR1, and the control terminal can be coupled to the third terminal of the second bias unit 120 to receive the operational voltage signal VREF.

The transistor T9 can include a first terminal, a second terminal and a control terminal, where the first terminal can be coupled to the control terminal of the transistor T8, and the second terminal can be coupled to the fifth terminal of the second bias unit 120 to receive the second reference voltage VR2.

The transistor T10 can include a first terminal, a second terminal and a control terminal, where the first terminal can be coupled to the fourth terminal of the second bias unit 120 to receive the first reference voltage VR1, the second terminal can be coupled to the second terminal of the second bias unit 120 to output the current IB2, and the control terminal can be coupled to the first terminal of the transistor T9.

The resistor R5 can include a first terminal and a second terminal, where the first terminal can be coupled to the control terminal of the transistor T9, and the second terminal can be coupled to the second terminal of the transistor T8.

The transistor SW3 and the resistance unit RU3 can form a variable resistance unit VRU. The variable resistance unit VRU can have a resistance controlled and changed according to the preheat control signal SH. The variable resistance unit VRU can include a first terminal, a second terminal and a control terminal.

The resistance unit RU3 can include a first terminal and a second terminal, where the first terminal can be the first terminal of the variable resistance unit VRU coupled to the second terminal of the transistor T8, and the second terminal can be the second terminal of the variable resistance unit VRU coupled to the fifth terminal of the second bias unit 120 to receive the second reference voltage VR2. Optionally, the resistance unit RU3 can further include a plurality of adjustment terminals, and the adjustment terminals can be coupled to the transistor SW3 according to requirements, as described below.

The transistor SW3 can include a first terminal, a second terminal and a control terminal, where the first terminal can be coupled to at least one of the adjustment terminals of the resistance unit RU3, the second terminal can be coupled to the fifth terminal of the second bias unit 120 to receive the second reference voltage VR2, and the control terminal can be the control terminal of the variable resistance unit VRU coupled to the first terminal of the second bias unit 120 to receive the preheat control signal SH. The transistor SW3 can be coupled in parallel with some or all of the resistors of the resistance unit RU3.

In FIG. 7, the resistance unit RU3 can include resistors R71, R72, R73, R74, R75, R76 and R77 and adjustment terminals N71, N72, N73, N74, N75 and N76. FIG. 7 is an example, and embodiments are not limited thereto. The number and locations of the resistors and adjustment terminals of the resistance unit RU3 can be changed according to requirements. In the example of FIG. 7, the first terminal of the transistor SW3 can be coupled to the adjustment terminal N72. In other words, the transistor SW3 can be coupled in parallel with a resistance circuit formed by the resistors R71 and R72 coupled in series. Please also refer to FIG. 2, the signal waveform of preheat control can have a pulse during the first period TH1 (in which the preheat control is enabled), and it means the amplifier A20 is preheated during the first period TH1. At this time, the operational voltage signal VREF can have the higher second signal level L2 (e.g. 3 volts), the preheat control signal SH can have the higher third signal level L3 (e.g. 0.5 volts), the transistor SW3 in FIG. 7 can be turned on, and the resistors R71 and R72 in the resistance unit RU3 can be bypassed. Hence, an equivalent resistance of the resistance unit RU3 (generated by the resistors R73, R74, R75, R76 and R77 coupled in series) can be lower, so the current IB2 can be higher. During the second period TH2 (in which the preheat control is disabled), the signal waveform of preheat control can be kept at a low signal level, the preheat control signal SH can have the lower fourth signal level L4 (e.g. 0 volts), and the transistor SW3 is tuned off. Hence, the equivalent resistance of the resistance unit RU3 (generated by the resistors R71, R72, R73, R74, R75, R76 and R77 coupled in series) can be higher in the second period TH2, and the current IB2 can be relatively low.

According to requirements, when the amplification control circuit 100 is generated through a manufacture process, the current IB2 used for preheating the amplifier A20 can be measured in a laboratory. When the first terminal of the transistor T3 is coupled to the adjustment terminal N71, the current IB2 can be lowest. When the first terminal of the transistor T3 is coupled to the adjustment terminal N72, the current IB2 can be increased. When the first terminal of the transistor T3 is coupled to the adjustment terminal N73, the current IB2 can be further increased. Hence, when the first terminal of the transistor T3 is coupled to the adjustment terminal N76, the current IB2 can have a maximum value. Hence, in other words, the first terminal of the transistor T3 can be coupled to a selected adjustment terminal to adjust the current IB2 used for preheating the amplifier A20. For example, before the mass production, the focused ion beam (FIB) can be used to change the adjustment terminal of the resistance unit RU3 coupled to the first terminal of the transistor SW3, and the current IB2 can be measured for the user to select a suitable adjustment terminal. The selected adjustment terminal can be coupled to the first terminal of the transistor SW3 for the mass production. In another embodiment, optionally, an additional selection circuit (e.g. single-pole multi-throw switch) can be disposed in the circuit, so the first terminal of the transistor SW3 can be coupled to one of the adjustment terminals N71 to N76 selectively to generate a more appropriate current IB2 for preheating the amplifier A20.

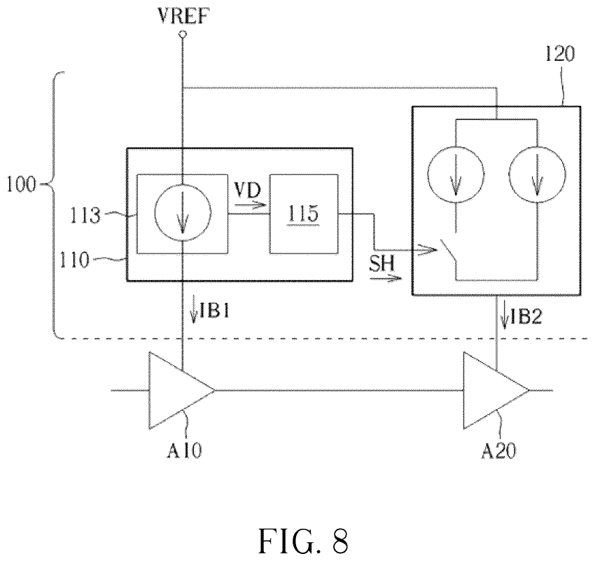

FIG. 8 illustrates the amplification control circuit 100 coupled to the amplifier A10 and the amplifier A20 according to another embodiment. As shown in FIG. 8, the output terminal of the amplifier A10 can be directly coupled to the input terminal of the amplifier A20. In other words, the amplifier A10 can be a previous stage of amplifier before the amplifier A20.

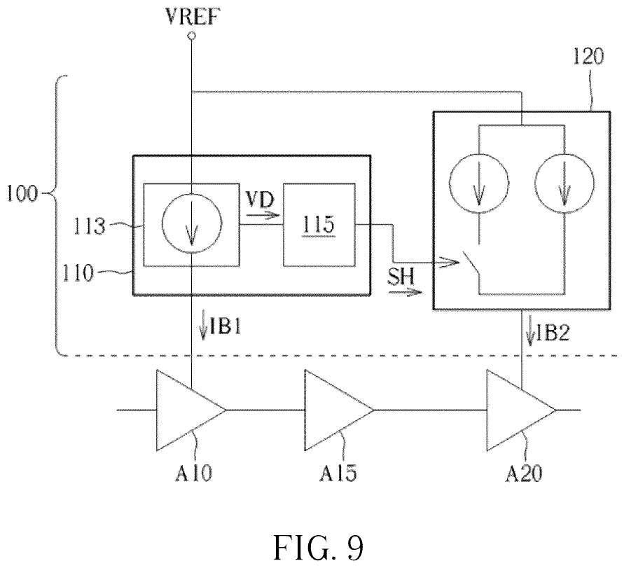

FIG. 9 illustrates the amplification control circuit 100 coupled to the amplifier A10, an amplifier A15 and the amplifier A20 according to another embodiment. The amplifier A10, the amplifier A15 and the amplifier A20 can be an input-stage amplifier, an intermediate-stage amplifier and an output-stage amplifier respectively. In FIG. 9, the output terminal of the amplifier A10 can be coupled to an input terminal of the middle stage amplifier A15, and an output terminal of the intermediate-stage amplifier A15 can be coupled to the input terminal of the amplifier A20. In other words, the intermediate-stage amplifier A15 can be disposed between the amplifier A10 and the amplifier A20. FIG. 9 is an example, and embodiments are not limited thereto. It is in the scope of embodiments to dispose a plurality of stages of amplifiers coupled in series between the amplifier A10 and the amplifier A20.

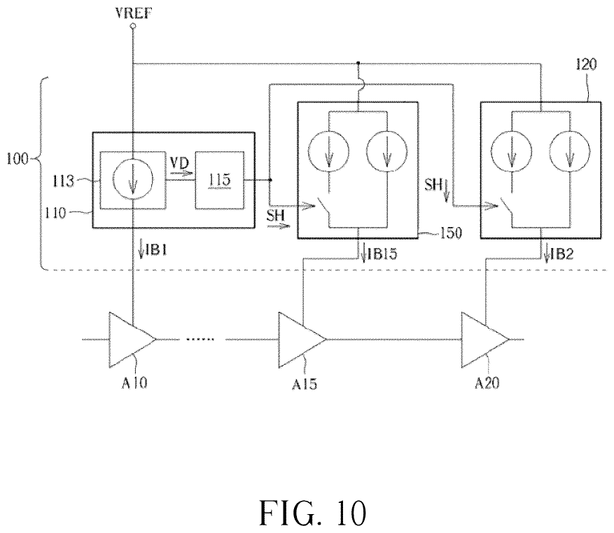

FIG. 10 illustrates the amplification control circuit 100 coupled to the amplifier A10, an amplifier A15 and the amplifier A20 according to another embodiment. Compared with FIG. 9, in FIG. 10, an intermediate-stage bias unit 150 can be coupled to the intermediate-stage amplifier A15. The intermediate-stage bias unit 150 can receive the preheat control signal SH to generate an intermediate-stage current IB15 to preheat the amplifier A15 for the amplifier A15 to reach thermal equilibrium earlier. The current IB15 in the first period TH1 can be higher than that in the second period TH2. The first period TH1 can start from a beginning of the change of the operational voltage signal VREF, and the second period TH2 can start from an end of the first period TH1. The current IB15 can be larger than one of the currents IB1 and IB2, and smaller than the other one of the currents IB1 and IB2. The circuit structure and operation of the intermediate-stage bias unit 150 can be similar to that of the second bias unit 120, so it is not repeatedly described. In the embodiment of FIG. 10, The amplifier A10, the amplifier A15 and the amplifier A20 can be an input-stage amplifier, an intermediate-stage amplifier and an output-stage amplifier respectively. The currents IB1, IB15 and IB2 can be bias currents for the amplifiers A10, A15 and A20 respectively to operate the amplifiers A10, A15 and A20 appropriately.

An embodiment provides an amplification control method corresponding to the embodiments of FIG. 1 to FIG. 10, and amplification control method can include following steps.

Step I: Receive the operational voltage signal VREF and output the current IB1 to the amplifier A10;

Step II: Generate the preheat control signal SH according to a change of the operational voltage signal VREF; and

Step III: Output the current IB2 to the amplifier A20 according to the preheat control signal SH.

In the method, the current IB2 in the first period (e.g. TH1) can be larger than the current IB2 in the second period (e.g. TH2). The first period (e.g. TH1) can start from a beginning of the change of the operational voltage signal VREF, and the second period (e.g. TH2) can start from an end of the first period (e.g. TH1).

In summary, by using the amplification control circuit 100 coupled to the amplifiers, it can be detected when an input-stage amplifier is turned on, and an output-stage amplifier is preheated correspondingly. Hence, the amplifier can reach thermal equilibrium earlier, reducing signal distortion. By adjusting the settings of the circuits, the time length and current value of preheating can be adjusted. Since there is no need to repeatedly dispose preheating circuits for multi-stage amplifiers, the area and complexity of the circuit are effectively reduced, which is helpful for solving problems in this field.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification control circuit, comprising
a first bias unit configured to receive an operational voltage signal, output a first current to a first amplifier, and generate a preheat control signal according to a change of the operational voltage signal; and
a second bias unit configured to output a second current to a second amplifier, and comprising a first terminal configured to receive the preheat control signal, and a second terminal configured to output the second current;
wherein a current value of the second current in a first period is larger than a current value of the second current in a second period, the first period starts from a beginning of the change of the operational voltage signal, and the second period starts from an end of the first period.

2. The amplification control circuit of claim 1, wherein the first amplifier is an input-stage amplifier, and the second amplifier is an output-stage amplifier.

3. The amplification control circuit of claim 1, wherein the first bias unit further comprises:
a main bias circuit comprising a first terminal configured to receive the operational voltage signal, a second terminal configured to output the first current, and a detection terminal configured to output a detection signal, wherein the change of the operational voltage signal is related to a change of the detection signal; and
a preheat signal generation circuit configured to generate the preheat control signal according to the change of the detection signal, and comprising a first terminal coupled to the detection terminal of the main bias circuit, and a second terminal configured to output the preheat control signal and coupled to the first terminal of the second bias unit.

4. The amplification control circuit of claim 3, wherein the preheat signal generation circuit is further configured to generate the preheat control signal according to the change of the detection signal and the change of the operational voltage signal concurrently.

5. The amplification control circuit of claim 3, wherein when the operational voltage signal is changed from a first signal level to a second signal level at a first time point, the preheat control signal is changed from a third signal level to a fourth signal level at a second time point, and the first time point precedes the second time point.

6. The amplification control circuit of claim 3, wherein:
the main bias circuit of the first bias unit further comprises:
a fourth terminal configured to receive a second reference voltage; and
a direct-current discharge unit comprising a first terminal coupled to the detection terminal of the main bias circuit, and a second terminal coupled to the fourth terminal of the main bias circuit; and
the preheat signal generation circuit further comprises:
a third terminal configured to receive the operational voltage signal;
a fifth terminal configured to receive the second reference voltage;
a time constant control unit comprising a first terminal coupled to the third terminal of the preheat signal generation circuit, and a second terminal; and
a logic unit comprising a first input terminal coupled to the first terminal of the preheat signal generation circuit, a second input terminal coupled to the second terminal of the time constant control unit, and an output terminal coupled to the second terminal of the preheat signal generation circuit;
wherein when the operational voltage signal is changed from a first signal level to a second signal level, the time constant control unit and the logic unit generate the preheat control signal according to the change of the operational voltage signal; and
when the operational voltage signal is changed from the second signal level to the first signal level, the logic unit provides a discharge path between the second input terminal and the first input terminal of the logic unit.

7. The amplification control circuit of claim 6, wherein the logic unit further comprises:
a first transistor comprising a first terminal coupled to the first input terminal of the logic unit, a second terminal, and a control terminal coupled to the second input terminal of the logic unit;
wherein when the operational voltage signal is changed from the second signal level to the first signal level, the logic unit provides the discharge path between the first input terminal and the second terminal of the logic unit; and
when the operational voltage signal is changed from the first signal level to the second signal level, the logic unit provides a signal transmission path between the first input terminal of the logic unit and the second terminal of the first transistor.

8. The amplification control circuit of claim 7, wherein the logic unit further comprises:
a second transistor comprising a first terminal coupled to the second terminal of the preheat signal generation circuit, a second terminal, and a control terminal coupled to the second terminal of the first transistor.

9. The amplification control circuit of claim 8, wherein the logic unit further comprises:
a second resistance unit comprising a first terminal, and a second terminal coupled to the first terminal of the second transistor.

10. The amplification control circuit of claim 9, wherein the second resistance unit of the preheat signal generation circuit further comprises:
a seventh transistor comprising a first terminal coupled to the first terminal of the second resistance unit, a second terminal coupled to the second terminal of the second resistance unit through a first resistor, and a control terminal coupled to the second terminal of the second resistance unit through a second resistor.

11. The amplification control circuit of claim 10, wherein the seventh transistor is a depletion transistor.

12. The amplification control circuit of claim 6, wherein the time constant control unit further comprises:
a first resistance unit comprising a first terminal coupled to the first terminal of the time constant control unit, and a second terminal coupled to the second input terminal of the logic unit; and
a capacitance unit comprising a first terminal coupled to the second terminal of the first resistance unit, and a second terminal.

13. The amplification control circuit of claim 12, wherein the first resistance unit further comprises:
a fifth transistor comprising a first terminal coupled to the first terminal of the first resistance unit, a second terminal, and a control terminal;
a first resistor comprising a first terminal coupled to the control terminal of the fifth transistor, and a second terminal coupled to the second terminal of the first resistance unit; and
a sixth transistor comprising a first terminal coupled to the second terminal of the fifth transistor, a second terminal coupled to the second terminal of the first resistance unit, and a control terminal coupled to the first terminal of the sixth transistor.

14. The amplification control circuit of claim 13, wherein the first resistance unit further comprises:
a second resistor comprising a first terminal coupled to the second terminal of the sixth transistor, and a second terminal coupled to the second terminal of the first resistance unit.

15. The amplification control circuit of claim 12, wherein the capacitance unit of the preheat signal generation circuit further comprises:
a plurality of capacitors each comprising a first terminal coupled to the first terminal of the capacitance unit, and a second terminal coupled to the second terminal of the capacitance unit.

16. The amplification control circuit of claim 3, wherein the main bias circuit of the first bias unit further comprises:
a third terminal configured to receive a first reference voltage;
a fourth terminal configured to receive a second reference voltage;
a first transistor comprising a first terminal coupled to the third terminal of the main bias circuit, a second terminal coupled to the detection terminal of the main bias circuit, and a control terminal;
a second transistor comprising a first terminal coupled to the control terminal of the first transistor, a second terminal, and a control terminal;
a second resistor comprising a first terminal coupled to the control terminal of the second transistor, and a second terminal coupled to the detection terminal of the main bias circuit;
a third transistor comprising a first terminal coupled to the third terminal of the main bias circuit, a second terminal coupled to the second terminal of the main bias circuit, and a control terminal coupled to the first terminal of the second transistor; and
a third resistor comprising a first terminal coupled to the detection terminal of the main bias circuit, and a second terminal coupled to the fourth terminal of the main bias circuit.

17. The amplification control circuit of claim 1, wherein the second bias unit further comprises:
a third terminal configured to receive the operational voltage signal;
a fourth terminal configured to receive a first reference voltage;
a fifth terminal configured to receive a second reference voltage;
an eighth transistor comprising a first terminal coupled to the fourth terminal of the second bias unit, a second terminal, and a control terminal coupled to the third terminal of the second bias unit;
a ninth transistor comprising a first terminal coupled to the control terminal of the eighth transistor, a second terminal coupled to the fifth terminal of the second bias unit, and a control terminal;
a tenth transistor comprising a first terminal coupled to the fourth terminal of the second bias unit, a second terminal coupled to the second terminal of the second bias unit, and a control terminal coupled to the first terminal of the ninth transistor;
a fifth resistor comprising a first terminal coupled to the control terminal of the ninth transistor, and a second terminal coupled to the second terminal of the eighth transistor; and
a variable resistance unit comprising a first terminal coupled to the second terminal of the eighth transistor, a second terminal coupled to the fifth terminal of the second bias unit, and a control terminal coupled to the first terminal of the second bias unit.

18. The amplification control circuit of claim 1, further comprising an intermediate-stage bias circuit, wherein:
the intermediate-stage bias circuit is configured to output an intermediate-stage current to an intermediate-stage amplifier, and comprises a first terminal configured to receive the preheat control signal, and a second terminal configured to output the intermediate-stage current, wherein a current value of the intermediate-stage current in the first period is larger than the current value of the second current in the second period; and
an output terminal of the first amplifier is coupled to an input terminal of the intermediate-stage amplifier, and an output terminal of the intermediate-stage amplifier is coupled to an input terminal of the second amplifier.

19. The amplification control circuit of claim 1, wherein the second current is larger than the first current.

20. An amplification control method comprising:
receiving an operational voltage signal and outputting a first current to a first amplifier;
generating a preheat control signal according to a change of the operational voltage signal; and
outputting a second current to a second amplifier according to the preheat control signal;
wherein a current value of the second current in a first period is larger than a current value of the second current in a second period, the first period starts from a beginning of the change of the operational voltage signal, and the second period starts from an end of the first period.
